(19) United States
(12) Patent Application Publication
(10) Pub. No.: US 2014/0158159 A1
(43) Pub. Date: Jun. 12, 2014

(54) SUBSTRATE CLEANING APPARATUS AND SUBSTRATE CLEANING METHOD

(71) Applicant: EBARA CORPORATION, Tokyo (JP)

(72) Inventor: Tomoatsu ISHIBASHI, Tokyo (JP)

(21) Appl. No.: 14/098,439

(22) Filed: Dec. 5, 2013

(30) Foreign Application Priority Data
Dec. 6, 2012 (JP) 2012-267569
Nov. 25, 2013 (JP) 2013-242717

(51) Int. Cl. H01L 21/67; H01L 21/02

(52) U.S. Cl. CPC H01L 21/67092; H01L 21/02057
USPC 134/6; 15/103.5

(57) ABSTRACT

A substrate cleaning apparatus performs scrub cleaning of a surface of a substrate by keeping a roll cleaning member and the surface of the substrate in contact with each other in the presence of a cleaning liquid. The substrate cleaning apparatus includes a first chemical liquid supply nozzle comprising a nozzle configured to supply a chemical liquid toward the substrate so that the chemical liquid is brought into contact with the surface of the substrate in a first contact area extending in an elongated shape, and a second chemical liquid supply nozzle comprising a nozzle configured to supply a chemical liquid toward the substrate so that the chemical liquid is brought into contact with the surface of the substrate in a second contact area spreading in an elliptical shape.

### CROSS REFERENCE TO RELATED APPLICATIONS

This document claims priorities to Japanese Patent Application No. 2012-267569, filed Dec. 6, 2012 and Japanese Patent Application No. 2013-242717 filed Nov. 25, 2013, the entire contents of which are hereby incorporated by reference.

### BACKGROUND OF THE INVENTION

1. Field of the Invention

The present invention relates to a substrate cleaning apparatus and a substrate cleaning method for performing scrub cleaning of a surface of a substrate, such as a semiconductor wafer, with an elongated cylindrical roll cleaning member extending horizontally, by rotating the substrate and the roll cleaning member each in one direction while keeping the roll cleaning member in contact with the surface of the substrate in the presence of a cleaning liquid. The substrate cleaning apparatus and the substrate cleaning method of the present invention can deal with a semiconductor wafer having a large diameter of 450 mm, and can be applied to a manufacturing process of a flat panel, a manufacturing process of an image sensor such as CMOS and CCD, a manufacturing process of a magnetic film for MRAM, and the like.

2. Description of the Related Art

As semiconductor devices are becoming finer these days, cleaning of various films, made of materials having different physical properties and formed on a substrate, is widely practiced. For example, in a damascene interconnect forming process for forming interconnects by filling a metal into interconnect trenches formed in an insulating film on the substrate surface, an extra metal on the substrate surface is polished away by chemical mechanical polishing (CMP) after the formation of damascene interconnects. A plurality of films such as a metal film, a barrier film and an insulating film, having different wettabilities with water, are exposed on the substrate surface after CMP.

Particles (defects) such as a residue of a slurry (slurry residue) that has been used in CMP, and metal polishing debris exist on the substrate surface having the exposed films, such as a metal film, a barrier film and an insulating film, by CMP. If cleaning of the substrate surface is insufficient and the residues remain on the substrate surface, the residues on the substrate surface may cause reliability problems such as the occurrence of leak from a residue portion, and poor adhesion. It is therefore necessary to clean the substrate surface, with a high cleaning level, on which the plurality of films, such as a metal film, a barrier film and an insulating film, having different wettabilities with water are exposed.

As a cleaning method for cleaning a substrate surface after CMP, there has been known a scrub cleaning method for cleaning a surface of a substrate, such as a semiconductor wafer, with an elongated cylindrical roll cleaning member (roll sponge or roll brush) by rotating the substrate and the roll cleaning member each in one direction while keeping the roll cleaning member in contact with the surface of the substrate in the presence of a cleaning liquid, as disclosed in Japanese laid-open patent publication Nos. 2010-278103, 2010-74191, and 2003-77876.

In conventional common damascene interconnects, there have been used tungsten as a metal and an oxide film as an insulating film respectively. Tungsten and the oxide film have hydrophilic surface properties, having a contact angle with water of not more than 15 degrees. Recently, in damascene interconnects, there have been increasingly used copper as an interconnect metal and a so-called low-k film, having a low dielectric constant, as an insulating film. Copper and the low-k film after CMP have hydrophobic surface properties, having a contact angle with water of not less than 30 degrees.

Particles (defects) such as a slurry residue, remaining on a substrate surface after cleaning, may cause a lowering of the yield of a semiconductor device. Therefore, a strong demand exists for the development of a substrate cleaning apparatus and a substrate cleaning method which can clean a substrate surface with a high cleaning level to reduce the number of defects remaining on the substrate surface even when the substrate surface has a hydrophobic property, such as a substrate surface after CMP in a semiconductor device whose surface condition is hydrophobic. To meet the above demand, in the case where the substrate surface on which copper and the low-k film are exposed by CMP is cleaned by scrub cleaning with the roll cleaning member extending horizontally in the presence of a cleaning liquid, it is necessary to supply a fresh cleaning liquid (chemical liquid or rinse liquid) stably without excess or deficiency to a cleaning area where the roll cleaning member is brought into contact with the substrate surface to perform scrub cleaning.

When the cleaning liquid such as a chemical liquid is supplied onto the surface of the substrate which is rotating in a horizontal state, a centrifugal force caused by rotation of the substrate acts on the cleaning liquid on the substrate surface. Further, when the substrate is rotated at a higher speed to enhance physical cleaning capability obtained by keeping the roll cleaning member in contact with the substrate, a larger centrifugal force acts on the cleaning liquid. Accordingly, the cleaning liquid which has been brought into contact with the substrate surface hardly moves inward from a contact point where the cleaning liquid is brought into contact with the substrate surface, but the cleaning liquid moves toward the outside of the substrate by the action of the centrifugal force. This tendency is particularly prominent in the cleaning liquid existing on the substrate surface which has a hydrophobic property because the substrate surface has a poor wettability with the cleaning liquid. Therefore, most of the cleaning liquid supplied onto the substrate surface is discharged outside of the substrate before the cleaning liquid reaches the cleaning area where the roll cleaning member is brought into contact with the substrate surface, and only a tiny amount of the cleaning liquid is used for the cleaning.

Further, a size of a silicon wafer is becoming larger from a maximum diameter of 300 mm to a maximum diameter of 450 mm, and thus it is expected to become more difficult for the cleaning liquid to spread over the entire surface of the substrate such as a silicon wafer having a diameter of 450 mm.

Furthermore, it is widely known that the wettability of the cleaning liquid with the substrate surface can be enhanced by mixing a surfactant into the cleaning liquid. However, in the most-advanced semiconductor devices, the surfactant is liable to remain, and thus it is a common trend to use a cleaning liquid free from the surfactant in a substrate cleaning apparatus for cleaning a substrate which has been processed by CMP.

### SUMMARY OF THE INVENTION

The present invention has been made in view of the above. It is therefore an object of the present invention to provide a substrate cleaning apparatus and a substrate cleaning method which can supply a fresh cleaning liquid (chemical liquid and rinse liquid) in an optimal way, when a surface of a substrate is cleaned by bringing a roll cleaning member into contact with the surface of the substrate which is rotating in a horizontal state, to a cleaning area on the surface of the substrate where the roll cleaning member and the surface of the substrate are brought into contact with each other, thereby cleaning the surface of the substrate efficiently with a high cleaning level to reduce the number of defects remaining on the surface of the substrate even when the surface of the substrate has a hydrophobic property.

According to one aspect of the present invention, there is provided a substrate cleaning apparatus for performing scrub cleaning of a surface of a substrate with an elongated roll cleaning member extending horizontally over substantially the entire length of a diameter of the substrate, by keeping the roll cleaning member and the surface of the substrate in contact with each other in the presence of a cleaning liquid while rotating the substrate and the roll cleaning member each in one direction, the substrate cleaning apparatus comprising: a first chemical liquid supply nozzle configured to supply a chemical liquid onto one half area of two areas on the surface of the substrate which are divided by a line formed by vertically projecting a rotational axis of the roll cleaning member onto the surface of the substrate, the first chemical liquid supply nozzle comprising a nozzle configured to supply the chemical liquid toward the substrate so that the chemical liquid is brought into contact with the surface of the substrate in a first contact area extending in an elongated shape; a second chemical liquid supply nozzle configured to supply a chemical liquid onto the one half area of the two areas, the second chemical liquid supply nozzle comprising a nozzle configured to supply the chemical liquid toward the substrate so that the chemical liquid is brought into contact with the surface of the substrate in a second contact area spreading in an elliptical shape; and a rinse liquid supply nozzle configured to supply a rinse liquid onto the surface of the substrate; wherein the first chemical liquid supply nozzle and the second chemical liquid supply nozzle are arranged so that the first contact area is located at a downstream side of the second contact area along a rotational direction of the substrate, and the rinse liquid supply nozzle is arranged so that the rinse liquid is brought into contact with the substrate at an upstream side of the second contact area along the rotational direction of the substrate.

The elliptical shape denotes hereinafter a rounded shape including an elongated elliptical shape, an oval shape and so on.

According to the present invention, the fresh cleaning liquid (chemical liquid and rinse liquid) can be supplied efficiently without excess or deficiency at long range and close range to the cleaning area, including a rotation center of the substrate and its vicinity, where the substrate and the roll cleaning member are brought into contact with each other, thereby cleaning the surface of the substrate efficiently with a high cleaning level to reduce the number of defects remaining on the surface of the substrate.

In a preferred aspect of the present invention, the one half area is a roll rolling-out-side area where the cleaning liquid is scraped out by rotation of the roll cleaning member.

According to the present invention, for example, in the case where the roll cleaning member on the surface of the substrate is rotated in a rightward direction (clockwise direction) as viewed from front, one half area, i.e., left half area where the cleaning liquid is scraped out by rotation of the roll cleaning member, of two areas on the surface of the substrate which are divided across the roll cleaning member, becomes the roll rolling-out-side area. By supplying the cleaning liquid onto the roll rolling-out-side area, the cleaning liquid can be supplied effectively to an inverse-direction cleaning area where the roll cleaning member and the substrate are brought into contact with each other in such a state that the direction of the rotational velocity of the substrate and the direction of the rotational velocity of the roll cleaning member are opposite to each other and a high physical cleaning capability is obtained.

In a preferred aspect of the present invention, the cleaning liquid is supplied to the roll cleaning member from a direction of a roll rolling-in-side area where the cleaning liquid is rolled in by rotation of the roll cleaning member.

According to the present invention, for example, in the case where the roll cleaning member on the surface of the substrate is rotated in a rightward direction (clockwise direction) as viewed from front, one half area, i.e., right half area where the cleaning liquid is rolled in by rotation of the roll cleaning member, of two areas on the surface of the substrate which are divided across the roll cleaning member, becomes the roll rolling-in-side area. By supplying the cleaning liquid onto the roll rolling-in-side area in this manner, the cleaning liquid can be retained by the roll cleaning member, thereby supplying the cleaning liquid effectively to the cleaning area.

In a preferred aspect of the present invention, the one half area comprises both of a roll rolling-out-side area where the cleaning liquid is scraped out by rotation of the roll cleaning member and a roll rolling-in-side area where the cleaning liquid is rolled in by rotation of the roll cleaning member.

According to the present invention, cleaning effect can be further enhanced by supplying the cleaning liquid to both the roll rolling-out-side area and the roll rolling-in-side area.

In a preferred aspect of the present invention, the first contact area is located at a downstream side along the rotational direction of the substrate in the one half area, and extends in substantially parallel to the roll cleaning member.

According to the present invention, the chemical liquid can be supplied more uniformly from a location in the vicinity of the roll cleaning member to the cleaning area where the substrate and the roll cleaning member are brought into contact with each other.

In a preferred aspect of the present invention, the first contact area extends in substantially parallel to the roll cleaning member from a location near an outer peripheral edge of the substrate and beyond a straight line which passes over a rotation center of the substrate and extends horizontally in a direction perpendicular to the rotational axis of the roll cleaning member.

According to the present invention, the chemical liquid can be supplied reliably from the first chemical liquid supply nozzle to the rotation center of the substrate and its vicinity.

In a preferred aspect of the present invention, in the case where an angle between a line formed by vertically projecting a center line of the chemical liquid ejection of the first chemical liquid supply nozzle onto the surface of the substrate, and a straight line which intersects with the projected line, formed by vertically projecting the center line of the chemical liquid ejection of the first chemical liquid supply nozzle, in the first contact area and extends in the direction perpendicular to the rotational axis of the roll cleaning member is taken as θ₁, and the angle as viewed in a clockwise direction from the straight line is assumed as a positive angle, said angle θ₁ is set to be −80°≦θ₁≦60°.

According to the present invention, the chemical liquid which has been supplied from the first chemical liquid supply nozzle can be prevented from being discharged outside from the outer circumferential edge of the substrate before reaching the cleaning area where the substrate and the roll cleaning member are brought into contact with each other.

In a preferred aspect of the present invention, a line formed by vertically projecting a center line of the chemical liquid ejection of the second chemical liquid supply nozzle intersects with a line extending along a rotational axis of the roll cleaning member at a rotation center of the substrate or at a downstream side of the rotation center of the substrate along the rotational direction of the substrate.

According to the present invention, the chemical liquid can be supplied reliably from the second chemical liquid supply nozzle to the rotation center of the substrate and its vicinity.

In a preferred aspect of the present invention, an angle between the line formed by vertically projecting the center line of the chemical liquid ejection of the second chemical liquid supply nozzle and the line extending along the rotational axis of the roll cleaning member is not less than 30° and less than 90°.

In a preferred aspect of the present invention, a line formed by vertically projecting a center line of the rinse liquid ejection of the rinse liquid supply nozzle intersects with a line extending along a rotational axis of the roll cleaning member at a rotation center of the substrate or at a downstream side of the rotation center of the substrate along the rotational direction of the substrate.

According to the present invention, the rinse liquid can be supplied reliably from the rinse liquid supply nozzle to the rotation center of the substrate and its vicinity.

In a preferred aspect of the present invention, an angle between the line formed by vertically projecting the center line of the rinse liquid ejection of the rinse liquid supply nozzle and the line extending along the rotational axis of the roll cleaning member is not less than 10° and not more than 60°.

According to another aspect of the present invention, there is provided a substrate cleaning method for performing scrub cleaning of a surface of a substrate with an elongated roll cleaning member extending horizontally over substantially the entire length of a diameter of the substrate, by keeping the roll cleaning member and the surface of the substrate in contact with each other in the presence of a cleaning liquid while rotating the substrate and the roll cleaning member each in one direction, the substrate cleaning method comprising: supplying a chemical liquid so that the chemical liquid is brought into contact with the surface of the substrate in a first contact area extending in an elongated shape in one half area of two areas on the surface of the substrate which are divided by a line formed by vertically projecting a rotational axis of the roll cleaning member onto the surface of the substrate; supplying a chemical liquid so that the chemical liquid is brought into contact with the surface of the substrate in a second contact area spreading in an elliptical shape and located at an upstream side of the first contact area along the rotational direction of the substrate in the one half area of the two areas; keeping the roll cleaning member in contact with the surface of the substrate to perform scrub cleaning of the surface of the substrate; and supplying a rinse liquid to rinse the surface of the substrate, after separating the roll cleaning member from the surface of the substrate and stopping supply of the chemical liquid from the first chemical liquid supply nozzle and the second chemical liquid supply nozzle, so that the rinse liquid is brought into contact with the substrate at an upstream side of the second contact area along the rotational direction of the substrate.

In a preferred aspect of the present invention, the method further comprises: supplying a rinse liquid so that the rinse liquid is brought into contact with the substrate at a third contact area located at an upstream side of the second contact area along the rotational direction of the substrate.

According to the present invention, the chemical liquid supplied onto the substrate can be diluted with the rinse liquid supplied onto the substrate.

According to the present invention, the fresh cleaning liquid (chemical liquid and rinse liquid) can be supplied efficiently without excess or deficiency at long range and close range to the cleaning area, including a rotation center of the substrate and its vicinity, where the substrate and the roll cleaning member are brought into contact with each other, thereby cleaning the surface of the substrate efficiently with a high cleaning level to reduce the number of defects remaining on the surface of the substrate.

### BRIEF DESCRIPTION OF THE DRAWINGS

FIG. 1 is a plan view showing an entire structure of a substrate processing apparatus incorporating a substrate cleaning apparatus according to an embodiment of the present invention;

FIG. 2 is a schematic perspective view showing the substrate cleaning apparatus, according to an embodiment of the present invention, which is used as a first cleaning unit in the substrate processing apparatus shown in FIG. 1;

FIG. 3 is a view for explanation of definitions of respective areas on a surface of a substrate;

FIG. 4 is a view for explanation of a rotational velocity of the substrate, a rotational velocity of a roll cleaning member, and a cleaning area;

FIG. 5 is a plan view showing the substrate cleaning apparatus according to the embodiment of the present invention;

FIG. 6 is a perspective view showing the substrate cleaning apparatus according to the embodiment of the present invention, as viewed from the back side;

FIG. 7 is a schematic elevational view showing the substrate cleaning apparatus shown in FIG. 5, illustration of a second chemical liquid supply nozzle and a rinse liquid supply nozzle being omitted;

FIG. 8 is a plan view showing schematically a state where a chemical liquid supplied onto the substrate from a first chemical liquid supply nozzle and a second chemical liquid supply nozzle and a rinse liquid supplied onto the substrate from a rinse liquid supply nozzle spread out after the contact with the substrate;

FIG. 9 is a perspective view showing a substrate cleaning apparatus according to another embodiment of the present invention;

FIG. 10 is a plan view of the substrate cleaning apparatus shown in FIG. 9;

FIG. 11 is a schematic plan view showing a substrate cleaning apparatus according to still another embodiment of the present invention;

FIG. 12 is a perspective view of the substrate cleaning apparatus shown in FIG. 11;

FIG. 13 is an elevational view as viewed from an arrow XIII of FIG. 12;

FIG. 14 is an enlarged perspective view showing a part of the roll cleaning member;

FIG. 15 is a graph showing the measured result of the number of defects on the surface of the substrate in Inventive Examples 1, 2 and 3 and Comparative Example;

FIG. 16 is a graph showing the measured result of an incidence rate of uneven distribution of defects in the Inventive Examples 1, 2 and 3, and the Comparative Example;

FIG. 17A is a view showing a state of the uneven distribution of defects over the substrate surface in the Inventive Example 1; and

FIG. 17B is a view showing a state of the uneven distribution of defects over the substrate surface in the Comparative Example.

### DETAILED DESCRIPTION

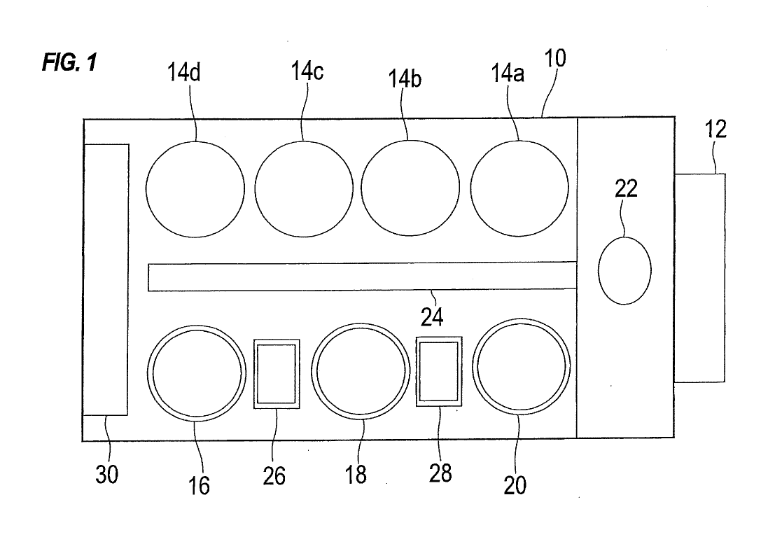

A substrate cleaning apparatus and a substrate cleaning method according to embodiments of the present invention will be described below with reference to FIGS. 1 through 17B.

FIG. 1 is a plan view showing an entire structure of a substrate processing apparatus incorporating a substrate cleaning apparatus according to an embodiment of the present invention. As shown in FIG. 1, the substrate processing apparatus includes a generally-rectangular housing 10, and a loading port 12 for placing thereon a substrate cassette storing a large number of substrates, such as semiconductor wafers. The loading port 12 is disposed adjacent to the housing 10 and is capable of placing thereon an open cassette, a SMIF (standard manufacturing interface) pod or a FOUP (front opening unified pod). Each of the SMIF and the FOUP is a hermetically sealed container which houses therein a substrate cassette and is covered with a partition wall, and thus can keep independent internal environment isolated from an external space.

In the housing 10, there are provided a plurality of (four in this embodiment) polishing units 14a, 14b, 14c, 14d, a first cleaning unit 16 and a second cleaning unit 18 each for cleaning a substrate after polishing, and a drying unit 20 for drying a substrate after cleaning. The polishing units 14a, 14b, 14c, 14d are arranged in the longitudinal direction of the substrate processing apparatus, and the cleaning units 16, 18 and the drying unit 20 are also arranged in the longitudinal direction of the substrate processing apparatus. In this example, the substrate cleaning apparatus according to the embodiment of the present invention is applied to the first cleaning unit 16. The second cleaning unit 18 may employ a cleaning unit which has the same configuration as the first cleaning unit 16.

A first transfer robot 22 is disposed in an area surrounded by the loading port 12, and the polishing unit 14a and the drying unit 20 which are located near the loading port 12. Further, a substrate transport unit 24 is disposed in parallel to the polishing units 14a, 14b, 14c, 14d. The first transfer robot 22 receives a substrate before polishing from the loading port 12 and transfers the substrate to the transport unit 24, and receives a substrate after drying from the drying unit 20 and returns the substrate to the loading port 12. The transport unit 24 transports a substrate transferred from the first transfer robot 22, and transfers the substrate between the transport unit 24 and the polishing units 14a, 14b, 14c, 14d.

Between the first cleaning unit 16 and the second cleaning unit 18, there is provided a second transfer robot 26 for transferring a substrate between the first cleaning unit 16 and the second cleaning unit 18. Between the second cleaning unit 18 and the drying unit 20, there is provided a third transfer robot 28 for transferring a substrate between the second cleaning unit 18 and the drying unit 20. In the housing 10, there is provided a control panel 30 for controlling operations of respective devices in the substrate processing apparatus.

In this example, the substrate cleaning apparatus according to the embodiment of the present invention is used as the first cleaning unit 16. A pencil-type cleaning apparatus in which a contact surface of a lower end of a cylindrical pencil-type cleaning member extending in the vertical direction is brought into contact with a surface of the substrate rotating horizontally and the cleaning member is moved in one direction while rotating the cleaning member to scrub-clean the substrate in the presence of a cleaning liquid, is used as the second cleaning unit 18. Further, a spin drying unit in which an IPA vapor is ejected toward a substrate rotating horizontally from a moving injection nozzle to dry the substrate and the substrate is rotated at a high rotational speed to dry the substrate by a centrifugal force, is used as the drying unit 20.

In this example, as the second cleaning unit 18, the pencil-type cleaning apparatus is used, but the substrate cleaning apparatus according to the embodiment of the present invention or a cleaning apparatus for cleaning a substrate surface by two-fluid jet cleaning may be used.

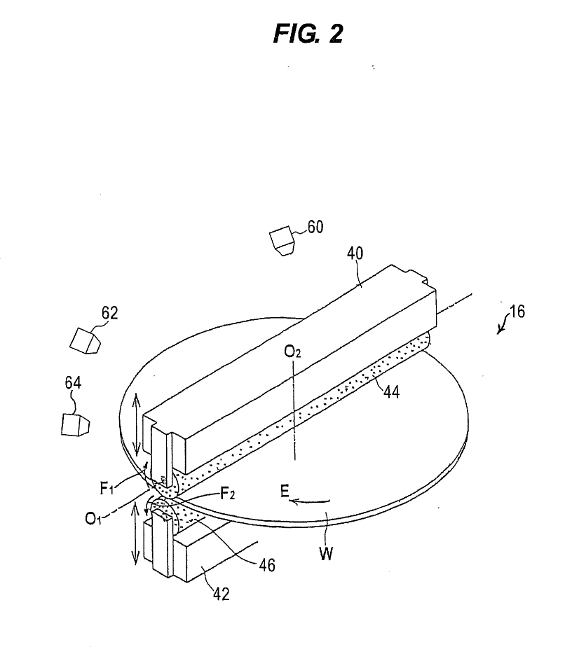

FIG. 2 is a schematic perspective view showing the substrate cleaning apparatus, according to an embodiment of the present invention, which is used as the first cleaning unit 16 shown in FIG. 1. As shown in FIG. 2, the first cleaning unit (substrate cleaning apparatus) 16 includes a plurality of (not shown) horizontally movable spindles for supporting a periphery of a substrate W, such as a semiconductor wafer, with its front surface facing upwardly, and horizontally rotating the substrate W, a vertically movable upper roll holder 40 disposed above the substrate W rotatably supported by the spindles, and a vertically movable lower roll holder 42 disposed below the substrate W rotatably supported by the spindles.

An elongated cylindrical upper roll cleaning member (roll sponge) 44, e.g., made of PVA, is rotatably supported by the upper roll holder 40. An elongated cylindrical lower roll cleaning member (roll sponge) 46, e.g., made of PVA, is rotatably supported by the lower roll holder 42.

The length of the upper roll cleaning member 44 is set to be slightly larger than the diameter of the substrate W. The upper roll cleaning member 44 is disposed in such a position that its central axis (rotational axis) O₁ is substantially perpendicular to the rotation center O₂ (rotational axis) of the substrate W, and that the upper roll cleaning member 44 extends over the entire length of the diameter of the substrate W. This enables cleaning of the entire length of the substrate W in a diametrical direction, from one end to the other end of the substrate W at the same time. The length of the lower roll cleaning member 46 is also set to be slightly larger than the diameter of the substrate W. As with the above-described cleaning of the front surface of the substrate W, cleaning of the entire length of substrate W in a diametrical direction, from one end to the other end of the reverse surface of the substrate W can be conducted at the same time.

The upper roll holder 40 is coupled to a drive mechanism (not shown) for vertically moving the upper roll holder 40 and rotating the upper roll cleaning member 44 in the direction shown by the arrow F₁ (clockwise direction as viewed from its left end). The upper roll cleaning member 44 is rotatably supported by the upper roll holder 40. The lower roll holder 42 is coupled to a drive mechanism (not shown) for vertically moving the lower roll holder 42 and rotating the lower roll cleaning member 46 in the direction shown by the arrow F₂ (counterclockwise direction as viewed from its left end). The lower roll cleaning member 44 is rotatably supported by the lower roll holder 42.

A configuration for cleaning the front surface (upper surface) of the substrate W in the first cleaning unit (substrate cleaning apparatus) 16 will be described below. In this case, the upper roll cleaning member 44 will be simply described as a roll cleaning member 44 in the following description. The reverse surface (lower surface) of the substrate W may be cleaned by substantially the same configuration as the configuration for cleaning the front surface (upper surface) of the substrate W, or may be cleaned by a conventional common roll scrub cleaning.

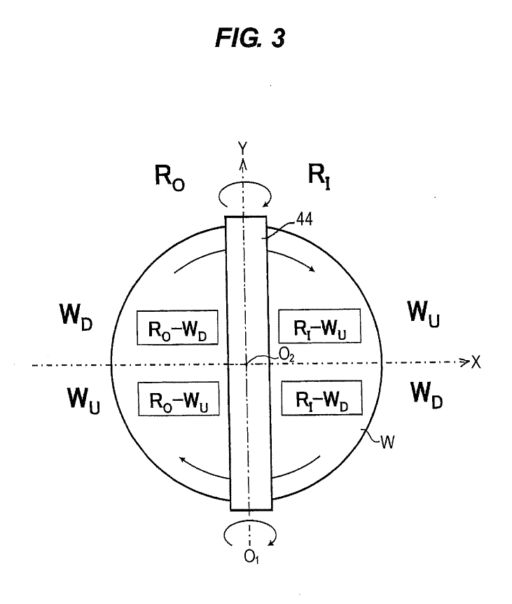

FIG. 3 is a view showing a positional relationship between the substrate W and the roll cleaning member 44, as viewed from above. As shown in FIG. 3, a straight line which passes over the rotation center O₂ of the substrate W and extends in a direction perpendicular to the rotational shaft O₁ of the roll cleaning member 44 is taken as an X-axis, and a straight line which extends along the rotational shaft O₁ of the roll cleaning member 44 is taken as a Y-axis. The roll cleaning member 44 is rotated in the clockwise direction as viewed from front, and the substrate W is rotated in the clockwise direction as viewed from above.

As shown in FIG. 3, it is assumed that the surface of the substrate W is divided into two, i.e., right and left, half areas R_{I}, R_{O} across the roll cleaning member 44, i.e., Y-axis. In the state shown in FIG. 3 where the roll cleaning member 44 is rotated in the clockwise direction, a right half area is defined as a roll rolling-in-side area R_{I}, and a left half area is defined as a roll rolling-out-side area R_{O}. The roll rolling-in-side area R_{I} is one half area (right side in FIG. 3) where the cleaning liquid is rolled in by rotation of the roll cleaning member 44, and the roll rolling-out-side area R_{O} is the other half area (left side in FIG. 3) where the cleaning liquid is scraped out by rotation of the roll cleaning member 44.

Further, each of the half area R_{I} and the half area R_{O} is further divided by the X-axis into an upstream-side area and a downstream-side area with respect to the rotational direction of the substrate W. An upstream-side area above the X-axis in the half area R_{I} is defined as a roll rolling-in and upstream-side area R_{I}−W_{U}, and a downstream-side area below the X-axis in the half area R₁ is defined as a roll rolling-in and downstream-side area R_{I}−W_{D}. An upstream-side area below the X-axis in the half area R_{O} is defined as a roll rolling-out and upstream-side area R_{O}−W_{U}, and a downstream-side area above the X-axis in the half area R_{O} is defined as a roll rolling-out and downstream-side area R_{O}−W_{D}.

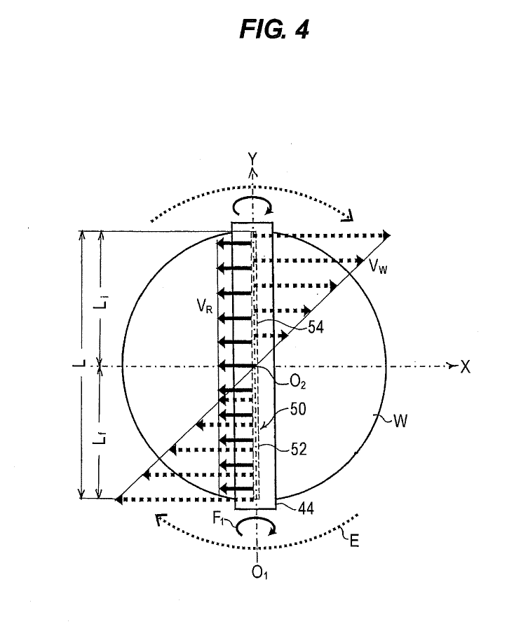

As shown in FIG. 4, an area, along the Y-axis, where the surface of the substrate W and the roll cleaning member 44 are brought into contact with each other becomes a cleaning area 50 having a length L. When the substrate W rotates about its rotation center O₂, the magnitude of the rotational velocity V_{W} of the substrate W in the cleaning area 50 is zero on the rotation center O₂ of the substrate W, and the direction (cleaning direction) of the rotational velocity V_{W} of the substrate W on one side of the rotation center O₂ is opposite to that on the other side of the rotation center O₂. On the other hand, when the roll cleaning member 44 rotates about its rotational axis O₁ (see FIG. 3), the magnitude of the rotational velocity V_{R} of the roll cleaning member 43 in the cleaning area 50 is constant over the entire length of the cleaning area 50, and the direction (cleaning direction) of the rotational velocity V_{R} is the same on both sides of the rotation center O₂ of the substrate W.

Therefore, it is assumed that the cleaning area 50 is divided into a forward-direction cleaning area 52 having a length L_{f} and lying on one side of the rotation center O₂ of the substrate W and an inverse-direction cleaning area 54 having a length Lᵢ and lying on the opposite side of the rotation center O₂ of the substrate W. In the forward-direction cleaning area 52, the direction of the rotational velocity V_{W} of the substrate W is the same as the direction of the rotational velocity V_{R} of the roll cleaning member 44. In the inverse-direction cleaning area 54, the direction of the rotational velocity V_{W} of the substrate W is opposite to the direction of the rotational velocity V_{R} of the roll cleaning member 44.

In the forward-direction cleaning area 52, the magnitude of the relative rotational velocity between the rotational velocity V_{W} of the substrate W and the rotational velocity V_{R} of the roll cleaning member 44 is the absolute value of the difference between the magnitudes of two rotational velocities and is relatively low, resulting in a low physical cleaning capability. Further, depending on the magnitude of the rotational velocity V_{W} of the substrate W and the magnitude of the rotational velocity V_{R} of the roll cleaning member 44, there may exist a region where the magnitude of the relative rotational velocity between the rotational velocity V_{W} of the substrate W and the rotational velocity V_{R} of the roll cleaning member 44 is zero (V_{W}=V_{R}) and the substrate W is not cleaned. It is considered that in this region where the substrate W is not cleaned, the substrate W is merely in contact with the roll cleaning member 44, and no scrub cleaning of the surface of the substrate W with the roll cleaning member 44 is performed. Rather, it is possible that residues and the like which have adhered to the roll cleaning member 44 may be pressed against the surface of the substrate W and re-adhere to the surface of the substrate W, thus causing contamination of the surface of the substrate W.

On the other hand, in the inverse-direction cleaning area 54, the magnitude of the relative rotational velocity between the rotational velocity V_{W} of the substrate W and the rotational velocity V_{R} of the roll cleaning member 44 is the sum of the magnitudes of the two rotational velocities and is relatively high, resulting in a high physical cleaning capability.

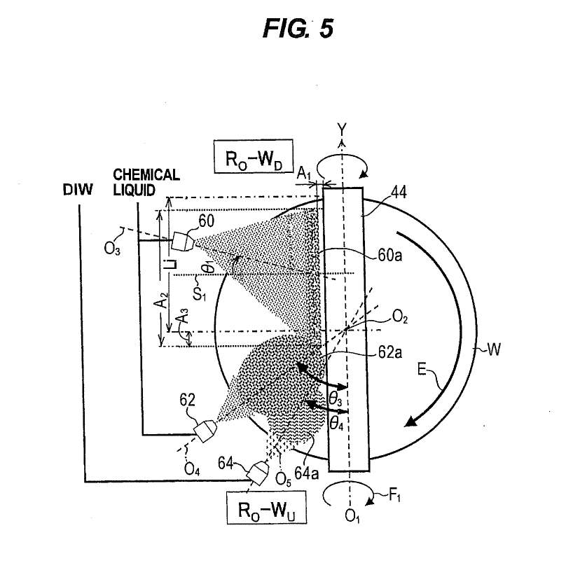

Accordingly, in this example, in order to supply a fresh cleaning liquid (chemical liquid and/or rinse liquid) efficiently without excess or deficiency to the inverse-direction cleaning area 54 including the rotation center O₂ of the substrate W, there are provided a first chemical liquid supply nozzle 60 and a second chemical liquid supply nozzle 62 for supplying a chemical liquid to the roll rolling-out-side area R_{O} of the substrate W, and a rinse liquid supply nozzle 64 for supplying a rinse liquid, i.e. a deionized water (DIW) in this example to the roll rolling-out-side area R_{O} of the substrate W, as shown in FIGS. 2 and 5. Other than the deionized water (DIW), a functional water such as a hydrogen water is used as the rinse liquid.

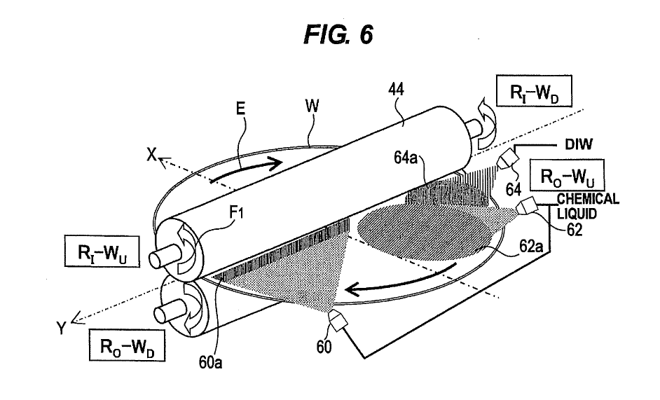

As shown in FIGS. 5 and 6, as the first chemical liquid supply nozzle 60, a fan-shaped nozzle is used to supply the chemical liquid toward the substrate W so that the chemical liquid is brought into contact with the surface of the substrate W in a first contact area 60a extending in an elongated shape having a small width. As the second chemical liquid supply nozzle 62, a conical nozzle is used to supply the chemical liquid toward the substrate W so that the chemical liquid is brought into contact with the surface of the substrate W in a second contact area 62a spreading in an elliptical shape. As the rinse liquid supply nozzle 64, a conical nozzle is used to supply the rinse liquid toward the substrate W so that the deionized water (DIW) as the rinse liquid is brought into contact with the surface of the substrate W in a third contact area 64a spreading in an elliptical shape. In this example, the fan-shaped nozzle is used as the first chemical liquid supply nozzle, and the conical nozzles are used as the second chemical liquid supply nozzle and the rinse liquid supply nozzle. However, the shapes of the respective nozzles are not limited to the above.

The first chemical liquid supply nozzle 60 and the second chemical liquid supply nozzle 62 are arranged so that the first contact area 60a is located at a downstream side of the second contact area 62a along the rotational direction E of the substrate W. The rinse liquid supply nozzle 64 is arranged so that the rinse liquid is brought into contact with the substrate at an upstream side of the second contact area 62a along the rotational direction E of the substrate W.

The most part of the first contact area 60a where the chemical liquid supplied from the first chemical liquid supply nozzle 60 is brought into contact with the surface of the substrate W is located in the roll rolling-out and downstream-side area R_{O}−W_{D} of the surface of the substrate W and is formed in substantially parallel to the roll cleaning member 44. In FIG. 5, the distance A₁ between the right edge of the first contact area 60a and the line formed by vertically projecting the outermost circumference of the roll cleaning member 44 onto the surface of the substrate W is preferably about 5 mm, or 5 mm or less.

The length A₂ of the first contact area 60a is not less than the length Lᵢ of the inverse-direction cleaning area 54 (A₂>Lᵢ), and one end portion of the first contact area 60a reaches the roll rolling-out and upstream-side area R_{O}−W_{U} of the surface of the substrate W. The length A₃ of the one end portion of the first contact area 60a, which extends beyond the roll rolling-out and downstream-side area R_{O}−W_{D} and into the roll rolling-out and upstream-side area R_{O}−W_{U} is preferably in the range of (⅙)R to ( 1/12)R (A3=(⅙)R to ( 1/12)R) when the radius of the substrate W is R. The outer peripheral end portion of the first contact area 60a reaches the location near the outer peripheral edge of the substrate W, along the roll cleaning member 44. Further, in the plane shown in FIG. 5, in the case where the angle between the center line O₃ of the chemical liquid ejection of the first chemical liquid supply nozzle 60 and the straight line S₁ which intersects with the center line O₃ of the chemical liquid ejection in the first contact area 60a and extends in a direction perpendicular to the roll cleaning member 44 is taken as θ₁, and the angle as viewed in the clockwise direction from the straight line S₁ is assumed as a positive angle, the angle θ₁ is set to be −80°≦θ₁≦60°. Each of the center lines O₃, O₄ of the chemical liquid ejection and the center line O₅ of the rinse liquid ejection is a center line which divides equally a spread angle (ejection angle in the plan view) formed by the liquid ejected from each nozzle and spreading out horizontally. The directions of the center lines O₃, O₄ and O₅ represent the directions of the respective nozzles as viewed from above.

By providing the first chemical liquid supply nozzle 60 in the manner described above, substantially the whole amount of the chemical liquid supplied onto the substrate W from the first chemical liquid supply nozzle 60 is more uniformly supplied onto the entire surface of the inverse-direction cleaning area 54 including the rotation center O₂ of the substrate W and its vicinity by the centrifugal force produced by rotation of the substrate W, without being discharged outside of the substrate W.

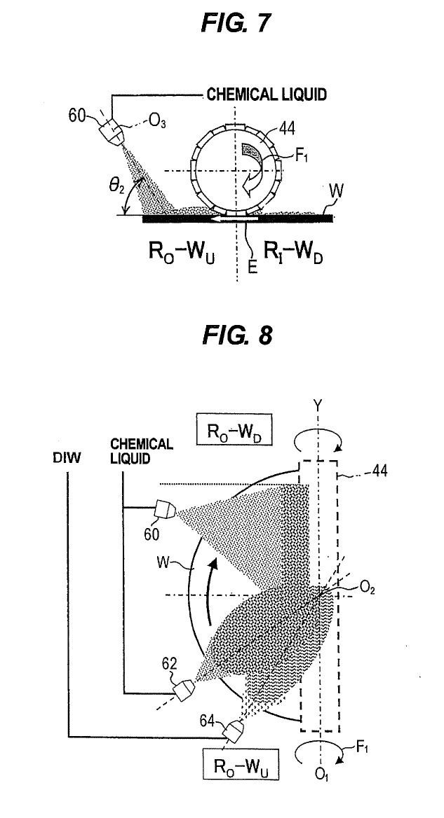

FIG. 7 is an elevational view showing the substrate cleaning apparatus shown in FIG. 5 as viewed from the side of the roll rolling-out and upstream-side area R_{O}−W_{U} and the roll rolling-in and downstream-side area R_{I}−W_{D}. In FIG. 7, illustration of the second chemical liquid supply nozzle 62 and the rinse liquid supply nozzle 64 is omitted.

As shown in FIG. 7, the angle θ₂ between the center line O₃ of the chemical liquid ejection of the first chemical liquid supply nozzle 60 and the horizontal plane along the substrate surface is set in the range of 5° to 60° (5°≦θ₂≦60°). The angle θ₂ is considered to be a supply-angle of the first chemical liquid with respect to the substrate W. The center line of the chemical liquid ejection in FIG. 7 is a center line which divides equally a spread angle (ejection angle in the elevational view) formed by the liquid ejected from the nozzle and spreading out. The direction of the center line represents the direction of the nozzle as viewed in the elevational view. By providing the first chemical liquid supply nozzle 60 in this manner, as shown in FIG. 8, the fresh chemical liquid which has been brought into contact with the surface of the substrate W spreads out uniformly in a lateral direction from the first contact area 60a as a center, thereby being distributed more uniformly in the inverse-direction cleaning area 54. FIG. 8 shows the state where the chemical liquid supplied onto the substrate W from the first chemical liquid supply nozzle 60 spreads out after the contact with the substrate W.

As shown in FIG. 5, the most part or the whole of the second contact area 62a where the chemical liquid supplied from the second chemical liquid supply nozzle 62 is brought into contact with the surface of the substrate W is located in the roll rolling-out and upstream-side area R_{O}−W_{U} on the surface of the substrate W and is formed into an elliptical shape. The elliptical shape includes an elongated elliptical shape and an oval shape.

In the plane of FIG. 5, the center line O₄ of the chemical liquid ejection of the second chemical liquid supply nozzle 62 intersects at the rotation center O₂ of the substrate W with a straight line (Y-axis) extending along the rotational axis O₁ of the roll cleaning member 44. The angle θ₃ between the center line O₄ of the chemical liquid ejection of the second chemical liquid supply nozzle 62 and the straight line (Y-axis) extending along the rotational axis O₁ of the roll cleaning member 44 is, for example, not less than 30° and less than 90° (30°≦θ₃≦90°). By providing the second chemical liquid supply nozzle 62 in this manner, the chemical liquid which has been brought into contact with the surface of the substrate W is distributed more uniformly over the entire area of the surface of the substrate W.

In FIG. 7, the supply-angle θ₂ of the first chemical liquid with respect to the substrate W has been explained. Here, a supply-angle of the second chemical liquid with respect to the substrate W will be considered. The angle between the center line O₄ of the chemical liquid ejection of the second chemical liquid supply nozzle 62 and the horizontal plane along the substrate surface is set in the range of 20° to 80°. By providing the second chemical liquid supply nozzle 62 in this manner, as shown in FIG. 8, the fresh chemical liquid which has been brought into contact with the surface of the substrate W spreads uniformly outward from the second contact area 62a as the center, thereby being distributed uniformly over the rotation center O₂ of the substrate W and its vicinity.

As shown in FIG. 5, the most part or the whole of the third contact area 64a where the deionized water (DIW) as a rinse liquid supplied from the rinse liquid supply nozzle 64 is brought into contact with the surface of the substrate W is located in the roll rolling-out and upstream-side area R_{O}−W_{U} on the surface of the substrate W and is formed into an elliptical shape. The elliptical shape includes an elongated elliptical shape and an oval shape.

In the plane of FIG. 5, the center line O₅ of the rinse liquid ejection of the rinse liquid supply nozzle 64 intersects at the rotation center O₂ of the substrate W with a straight line (Y-axis) extending along the rotational axis O₁ of the roll cleaning member 44. The angle θ₄ between the center line O₅ of the rinse liquid ejection of the rinse liquid supply nozzle 64 and the straight line (Y-axis) extending along the rotational axis θ₁ of the roll cleaning member 44 is, for example, not less than 10° and not more than) 60° (10°≦θ₄≦60°). By providing the rinse liquid supply nozzle 64 in this manner, the deionized water (DIW) as a rinse liquid which has been brought into contact with the surface of the substrate W is distributed more uniformly over the entire area of the surface of the substrate W. The relationship between θ₃ and θ₄ is set to be always θ₃>θ₄.

Then, a supply-angle of the rinse liquid with respect to the substrate W will be considered. The angle between the center line O₅ of the rinse liquid ejection of the rinse liquid supply nozzle 64 and the horizontal plane along the substrate surface is in the range of 20° to 80° and is set to be smaller than the angle between the center line O₄ of the chemical liquid ejection of the second chemical liquid supply nozzle 62 and the horizontal plane. By providing the rinse liquid supply nozzle 62 in this manner, as shown in FIG. 8, the rinse liquid which has been brought into contact with the surface of the substrate W spreads uniformly outward from the third contact area 64a as the center, thereby being distributed uniformly over the rotation center O₂ of the substrate W and its vicinity. In the case where the rinse liquid from the rinse liquid supply nozzle 64 and the chemical liquid from the second chemical liquid supply nozzle 62 are simultaneously supplied toward the substrate W, the chemical liquid is supplied onto the surface of the substrate W from a position located above a supply position of the rinse liquid.

FIG. 8 shows schematically a state where the chemical liquid supplied onto the substrate W from the first chemical liquid supply nozzle 60 and the second chemical liquid supply nozzle 62, and the deionized water as a rinse liquid supplied onto the substrate W from the rinse liquid supply nozzle 64 spread out after the contact with the substrate W.

In this example, the chemical liquid is supplied from the first chemical liquid supply nozzle 60 and the second chemical liquid supply nozzle 62 onto the roll rolling-out-side area R_{O} of the surface (upper surface) of the substrate W while rotating the substrate W in a horizontal state, and the roll cleaning member 44 is rotated and lowered to be brought into contact with the surface of the rotating substrate W, thereby performing scrub cleaning of the entire surface of the substrate W with the roll cleaning member 44 in the presence of the chemical liquid.

At this time, as described above, the chemical liquid is supplied from the second chemical liquid supply nozzle 62 toward the substrate W so that the chemical liquid is brought into contact with the substrate W in a second contact area 62a spreading in an elliptical shape at an upstream side of the roll rolling-out-side area R_{O} with respect to the rotational direction of the substrate W, and the chemical liquid is supplied from the first chemical liquid supply nozzle 60 toward the substrate W so that the chemical liquid is brought into contact with the substrate W in a first contact area 60a extending in an elongated shape having a small width at a downstream side of the roll rolling-out-side area R_{O} with respect to the rotational direction of the substrate W. With this configuration, the fresh chemical liquid can be supplied efficiently without excess or deficiency at long range and close range to the inverse-direction cleaning area 54 including the rotation center O₂ of the substrate W and its vicinity. Accordingly, the surface of the substrate W can be cleaned efficiently with a high cleaning level and the number of defects remaining on the surface of the substrate W can be reduced. In other words, the above inventive configuration can solve the conventional problem such that the chemical liquid which has been supplied onto the surface of the substrate W is discharged promptly outside from the outer circumferential edge of the substrate W before reaching the inverse-direction cleaning area 54 and thus the supplied chemical liquid makes little contribution to the cleaning of the substrate surface.

In the case where the chemical liquid supplied from the first chemical liquid supply nozzle 60 and the second chemical liquid supply nozzle 62 onto the roll rolling-out-side area R_{O} of the substrate W is diluted with a deionized water, a deionized water is used as a rinse liquid and the deionized water is supplied from the rinse liquid supply nozzle 64 toward the substrate W at the same time as the supply of the chemical liquid. At this time, in this example, the deionized water (rinse liquid) is brought into contact with the substrate W at the upstream side of the second contact area 62a along the rotational direction of the substrate W, and accordingly the chemical liquid supplied from the second chemical liquid supply nozzle 62 and the rinse liquid (deionized water) supplied from the rinse liquid supply nozzle 64 are mixed uniformly and conveyed to the inverse-direction cleaning area 54.

Then, after the roll cleaning member 44 is separated from the surface of the substrate W while rotating the substrate W in a horizontal state, the rinse liquid such as a deionized water (DIW) is supplied from the rinse liquid supply nozzle 64 onto the surface (upper surface) of the substrate W to rinse the surface of the substrate W, thereby removing the chemical liquid remaining on the surface of the substrate W immediately after cleaning.

In the substrate processing apparatus shown in FIG. 1, the substrate taken out from a substrate cassette inside the loading port 12 is transferred to one of the polishing units 14a, 14b, 14c, 14d, and the surface of the substrate is polished by the specified polishing unit. The surface of the substrate which has been polished is roughly cleaned in the first cleaning unit (substrate cleaning apparatus) 16, and is then finally cleaned in the second cleaning unit (pencil-type cleaning apparatus) 18. Then, the cleaned substrate is removed from the second cleaning unit 18 and transferred to the drying unit 20 where the substrate is dried. Thereafter, the dried substrate is returned into the substrate cassette inside the loading port 12.

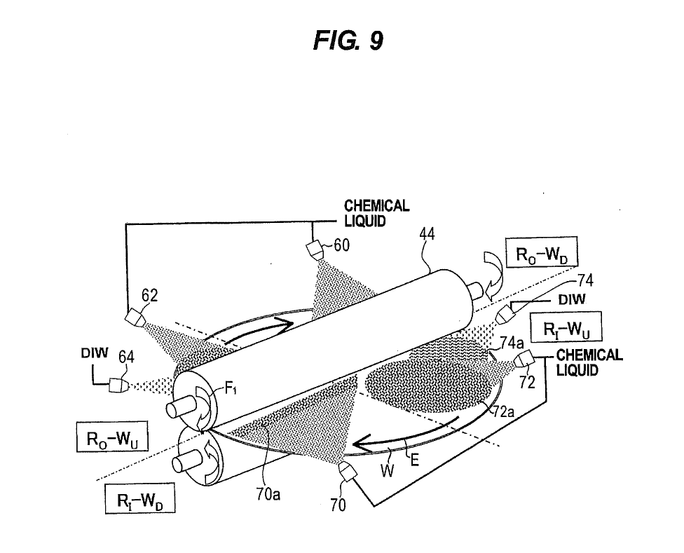

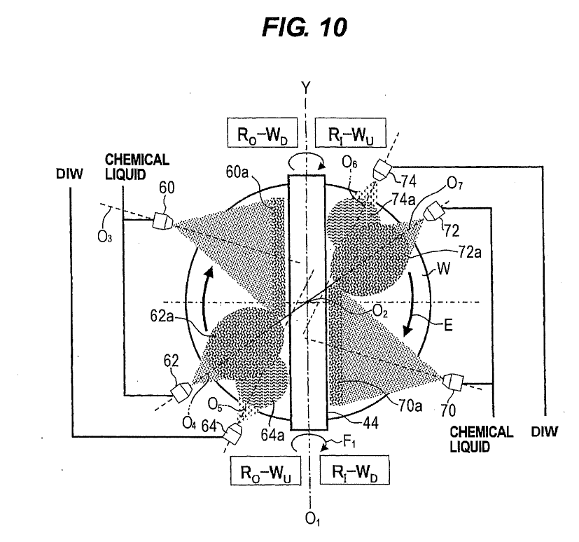

FIG. 9 is a perspective view showing a substrate cleaning apparatus according to another embodiment of the present invention, and FIG. 10 is a plan view of the substrate cleaning apparatus shown in FIG. 9. This embodiment differs from the above-described embodiment in the following respects.

Specifically, according to the substrate cleaning apparatus of this embodiment, in the roll rolling-in-side area R_{I} also, there are provided a first chemical liquid supply nozzle 70 and a second chemical liquid supply nozzle 72 each for supplying the chemical liquid, and a rinse liquid supply nozzle 74 for supplying a deionized water (DIW), in this example, as a rinse liquid. As the first chemical liquid supply nozzle 70, a fan-shaped nozzle is used to supply the chemical liquid toward the substrate W so that the chemical liquid is brought into contact with the surface of the substrate Win a first contact area 70a extending in an elongated shape having a small width. As the second chemical liquid supply nozzle 72, a conical nozzle is used to supply the chemical liquid toward the substrate W so that the chemical liquid is brought into contact with the surface of the substrate W in a second contact area 72a spreading in an elliptical shape. As the rinse liquid supply nozzle 74, a conical nozzle is used to supply the rinse liquid toward the substrate W so that the deionized water (DIW) as the rinse liquid is brought into contact with the surface of the substrate W in a third contact area 74a spreading in an elliptical shape. In this embodiment, the fan-shaped nozzle is used as the first chemical liquid supply nozzle, and the conical nozzles are used as the second chemical liquid supply nozzle and the rinse liquid supply nozzle. However, the shapes of the respective nozzles are not limited to the above. The elliptical shape includes an elongated elliptical shape and an oval shape.

The first chemical liquid supply nozzle 70 and the second chemical liquid supply nozzle 72 are arranged so that the first contact area 70a is located at a downstream side of the second contact area 72a along the rotational direction E of the substrate W. The rinse liquid supply nozzle 74 is arranged so that the rinse liquid is brought into contact with the substrate at an upstream side of the second contact area 72a along the rotational direction E of the substrate W.

In the plane shown in FIG. 10, the center line O₅ of the rinse liquid ejection of the rinse liquid supply nozzle 64 for supplying the rinse liquid onto the roll rolling-out-side area R_{O} of the substrate W intersects with the line (Y-axis) extending along the rotational axis O₁ of the roll cleaning member 44 at a downstream side of the rotation center O₂ of the substrate W along the rotational direction E of the substrate W. The center line O₆ of the rinse liquid ejection of the rinse liquid supply nozzle 74 for supplying the rinse liquid onto the roll rolling-in-side area R₁ of the substrate W intersects with the line (Y-axis) extending along the rotational axis O₁ of the roll cleaning member 44 at a downstream side of the rotation center O₂ of the substrate W along the rotational direction E of the substrate W. This configuration can solve a problem that when the rinse liquid is supplied from the rinse liquid supply nozzles 64, 74 toward the substrate W at the same time, the rinse liquid supplied from the rinse liquid supply nozzle 64 and the rinse liquid supplied from the rinse liquid supply nozzle 74 collide with each other at their forward ends to create a stagnation of the rinse liquid which causes insufficient rinsing.

In this embodiment, in the plane shown in FIG. 10, the center line O₄ of the chemical liquid ejection of the second chemical liquid supply nozzle 62 intersects with the line (Y-axis) extending along the rotational axis O₁ of the roll cleaning member 44 at the rotation center O₂ of the substrate W. Further, the center line O₇ of the chemical liquid ejection of the second chemical liquid supply nozzle 72 for supplying the chemical liquid onto the roll rolling-in-side area R₁ intersects with the line (Y-axis) extending along the rotational axis O₁ of the roll cleaning member 44 at the rotation center O₂ of the substrate W. However, as with the rinse liquid supply nozzles 64, 74 shown in FIG. 10, the center line O₄ of the chemical liquid ejection of the second chemical liquid supply nozzle 62 for supplying the chemical liquid onto the roll rolling-out-side area R_{O} of the substrate W may intersect with the line (Y-axis) extending along the rotational axis O₁ of the roll cleaning member 44 at a downstream side of the rotation center O₂ of the substrate W along the rotational direction of the substrate W, and the center line O₇ of the chemical liquid ejection of the second chemical liquid supply nozzle 72 for supplying the chemical liquid onto the roll rolling-in-side area R₁ of the substrate W may also intersect with the line (Y-axis) extending along the rotational axis O₁ of the roll cleaning member 44 at a downstream side of the rotation center O₂ of the substrate W along the rotational direction of the substrate W.

In this embodiment, in a state where the substrate W is rotated in a horizontal state, the chemical liquid is supplied from the first chemical liquid supply nozzle 60 and the second chemical liquid supply nozzle 62 onto the roll rolling-out-side area R_{O} of the surface (upper surface) of the substrate W. At the same time, while the chemical liquid is supplied from the first chemical liquid supply nozzle 70 and the second chemical liquid supply nozzle 72 onto the roll rolling-in-side area R₁ of the surface (upper surface) of the substrate W, the roll cleaning member 44 is rotated and lowered to be brought into contact with the surface of the rotating substrate W, thereby performing scrub cleaning of the entire surface of the substrate W with the roll cleaning member 44 in the presence of the chemical liquid. At this time, as described above, in the case where the chemical liquid supplied from the first chemical liquid supply nozzle 70 and the second chemical liquid supply nozzle 72 onto the roll rolling-in-side area R₁ of the substrate W is diluted with a deionized water, a deionized water is used as a rinse liquid and the deionized water is supplied from the rinse liquid supply nozzle 74 toward the substrate W at the same time as the supply of the chemical liquid.

As described above, the chemical liquid is supplied from the first chemical liquid supply nozzle 60 and the second chemical liquid supply nozzle 62 onto the roll rolling-out-side area R_{O} of the surface (upper surface) of the substrate W. At the same time, the chemical liquid is supplied from the first chemical liquid supply nozzle 70 and the second chemical liquid supply nozzle 72 onto the roll rolling-in-side area R_{I} of the surface (upper surface) of the substrate W. With this configuration, the fresh chemical liquid can be supplied efficiently without excess or deficiency at long range and close range to the forward-direction cleaning area 52 as well as the inverse-direction cleaning area 54 including the rotation center O₂ of the substrate W and its vicinity. Accordingly, the surface of the substrate W can be cleaned efficiently with a high cleaning level and the number of defects remaining on the surface of the substrate W can be reduced.

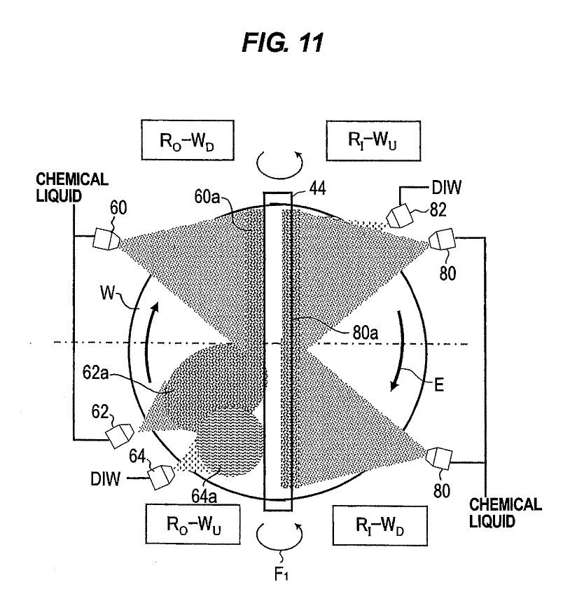

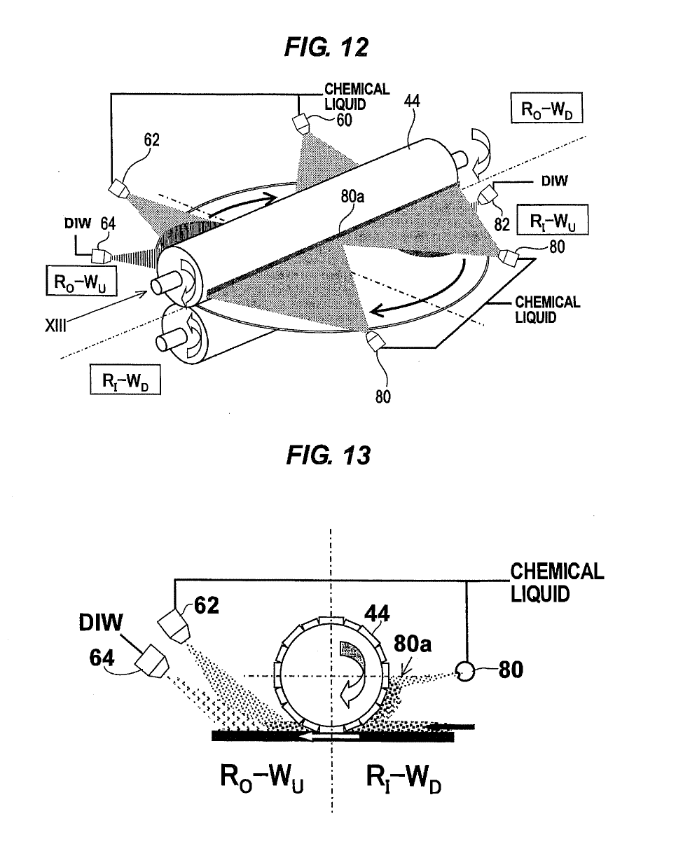

FIG. 11 is a schematic plan view showing a substrate cleaning apparatus according to still another embodiment of the present invention. FIG. 12 is a perspective view of the substrate cleaning apparatus shown in FIG. 11. FIG. 13 is an elevational view as viewed from an arrow XIII of FIG. 12. In FIG. 13, illustration of the first chemical liquid supply nozzle 60 and the second rinse liquid supply nozzle 82 of the substrate cleaning apparatus shown in FIG. 12 is omitted. This embodiment differs from the embodiment shown in FIGS. 2 through 8 in the following respects.

Specifically, in the substrate cleaning apparatus of this embodiment, there are provided a third chemical liquid supply nozzle 80 (a pair of third chemical liquid supply nozzles 80 in FIG. 12) for ejecting a chemical liquid toward substantially the entire length of the longitudinal direction of the roll cleaning member 44 located at the roll rolling-in-side area R_{I} of the substrate W, and a second rinse liquid supply nozzle 82 for supplying a rinse liquid to the roll rolling-in-side area R_{I} of the substrate Win an elliptical shape.

As shown in FIGS. 12 and 13, the third chemical liquid supply nozzle 80 comprises a fan-shaped nozzle for supply the chemical liquid toward the roll cleaning member 44 so that the chemical liquid is brought into contact with the surface of the roll cleaning member 44 located at the roll rolling-in-side area R₁ of the substrate W in a fourth contact area 80a extending in an elongated shape having a small width. In this embodiment, fan-shaped nozzles are used as the first chemical liquid supply nozzle and the third chemical liquid supply nozzle, and conical nozzles are used as the second chemical liquid supply nozzle, the rinse liquid supply nozzle and the second rinse liquid supply nozzle. However, the shapes of the respective nozzles are not limited to the above. The elliptical shape includes an elongated elliptical shape and an oval shape.

In this embodiment, in a state where the substrate W is rotated in a horizontal state, the chemical liquid is supplied from the first chemical liquid supply nozzle 60 and the second chemical liquid supply nozzle 62 onto the roll rolling-out-side area R_{O} of the surface (upper surface) of the substrate W. At the same time, while the chemical liquid is supplied from the third chemical liquid supply nozzle 80 to the roll cleaning member 44, the roll cleaning member 44 is rotated and lowered to be brought into contact with the surface of the rotating substrate W, thereby performing scrub cleaning of the entire surface of the substrate W with the roll cleaning member 44 in the presence of the chemical liquid. In the case where the chemical liquid supplied from the third chemical liquid supply nozzle 80 to the roll cleaning member 44 is diluted with a deionized water, a deionized water is used as a rinse liquid and the deionized water is supplied from the second rinse liquid supply nozzle 82.

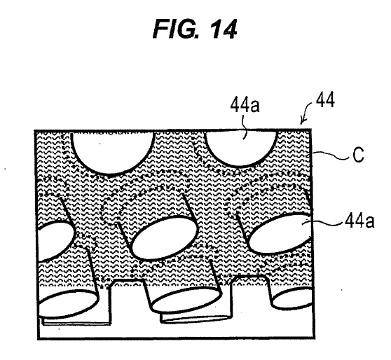

In this embodiment, before a certain portion of the roll cleaning member 44 is moved into the cleaning area 50 which is a contact portion of the roll cleaning member 44 with the surface of the substrate W, a fresh chemical liquid is supplied intentionally to the certain portion of the roll cleaning member 44 to allow the certain portion of the roll cleaning member 44 to absorb the fresh chemical liquid and then discharge the fresh chemical liquid therefrom when the roll cleaning member made of a sponge or the like is compressed, thereby improving the cleaning capability. At this time, as shown in FIG. 14, the cleaning capability can be improved by containing the chemical liquid C not only in the interior of the roll cleaning member made of the sponge or the like but also in spaces between projections 44a of the roll cleaning member made of the sponge or the like.

Specifically, a number of projections 44a are provided on the general roll cleaning member 44 made of PVA as shown in FIG. 14, and these projections 44a mainly contributes to cleaning of the substrate using a chemical liquid (cleaning liquid) supplied thereto. The scrub cleaning by contact is performed instantaneously by each of the projections 44a, and the cleaning of the substrate is performed instantaneously by the upper end of the projection 44a and the cleaning liquid.

Each of the upper end surfaces of the projections 44a is configured to have a coated film, which is not fully coated, and provides a physical contact surface for cleaning. However, the side surface of the projection 44a, except for the upper end surface thereof, generally does not have a coated film, but has a sponge-structure. Generally, it is considered that the chemical liquid is absorbed into the sponge-structure of the roll cleaning member when the projections 44a which have been compressed by contact with the substrate W at the time of cleaning are recovered in their shapes. However, it is observed that the chemical liquid which has been absorbed in the sponge-structure is reduced in amount by the centrifugal force or the like while the roll cleaning member 44 makes one revolution, and thus the chemical liquid hardly exists in the interiors of the projections 44a which exert an effect on cleaning.

Therefore, in this embodiment, in a state in which the projections 44a are not compressed, i.e. at the time when the sponge-structure is held, the chemical liquid is supplied to the roll cleaning member 44 so that the chemical liquid enters the spaces between projections 44a, thereby absorbing the chemical liquid promptly in the interiors of the projections 44a by the sponge-structure on their side surfaces of the projections 44a.

In this manner, in the cleaning performed by the contact between the rotating substrate W and the roll cleaning member 44, the chemical liquid supplied to and conveyed by the substrate W and the fresh chemical liquid physically supplied onto a rubbed surface of the substrate W from the interiors of the projections 44a when the roll cleaning member 44 is brought into contact with the substrate W, are supplied to the cleaning area 50, and thus a high cleaning effect can be obtained.

The most effective method for supplying the chemical liquid to the roll cleaning member 44 is to supply the chemical liquid at the upstream side of the roll cleaning member 44 along the rotational direction of the substrate W. In this manner, the chemical liquid can be supplied deliberately to the inverse-direction cleaning area 54 having a high cleaning capability where the rotational direction of the roll cleaning member 44 is opposite to the rotational direction of the substrate W. Further, when the chemical liquid is supplied also at the downstream side of the roll cleaning member 44 along the rotational direction of the substrate W, the chemical liquid which is likely to be insufficient in the cleaning area 50 can be secured easily in such a case where the chemical liquid is likely to be discharged to the outside of the substrate by the centrifugal force caused by rotation of the substrate.

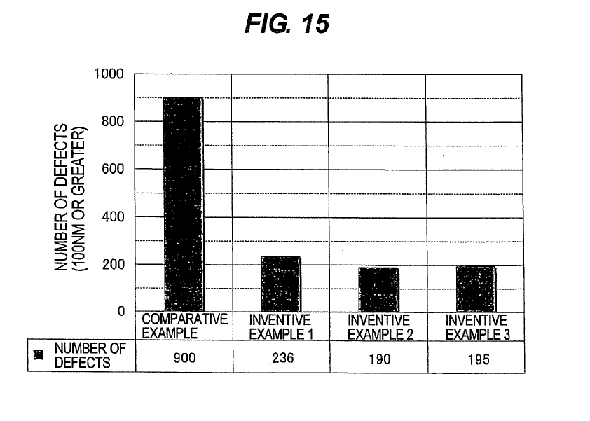

A surface (low-k film) of a sample substrate which includes a low-k film (k=2.4) having a hydrophobic surface property was polished by a polishing unit, and the polished surface (low-k film surface) of the sample substrate was cleaned using the first cleaning unit (substrate cleaning apparatus) 16 shown in FIGS. 2 through 8. After the cleaned sample substrate was dried with IPA (Iso-Propyl Alcohol), the number of particles (defects) having a size of 100 nm or greater that remained on the surface of the sample substrate was measured. The measured result is shown as Inventive Example 1 in FIG. 15. Similarly, a sample substrate (low-k film surface) was cleaned using the substrate cleaning apparatus shown in FIGS. 9 and 10. Then, the cleaned sample substrate was dried with IPA (Iso-Propyl Alcohol) and the number of particles (defects) having a size of 100 nm or greater that remained on the surface of the sample substrate was measured in the same manner as the Inventive Example 1. The measured result is shown as Inventive Example 2. A sample substrate (low-k film surface) was cleaned using the substrate cleaning apparatus shown in FIGS. 11 through 13. Then, the cleaned sample substrate was dried with IPA (Iso-Propyl Alcohol) and the number of particles (defects) having a size of 100 nm or greater was measured in the same manner as the Inventive Example 1. The measured result is shown as Inventive Example 3.

A sample substrate (low-k film surface) was cleaned using a general conventional cleaning unit. The cleaned sample substrate was dried with IPA (Iso-Propyl Alcohol) and the number of particles (defects) having a size of 100 nm or greater was measured in the same manner as the Inventive Example 1. The measured result is shown as Comparative Example in FIG. 15.

It is understood from FIG. 15 that the number of defects having a size of 100 nm or greater that remained on the surface of the sample substrate after cleaning is much smaller in Inventive Examples 1, 2 and 3 than in Comparative Example (about ¼ or less).

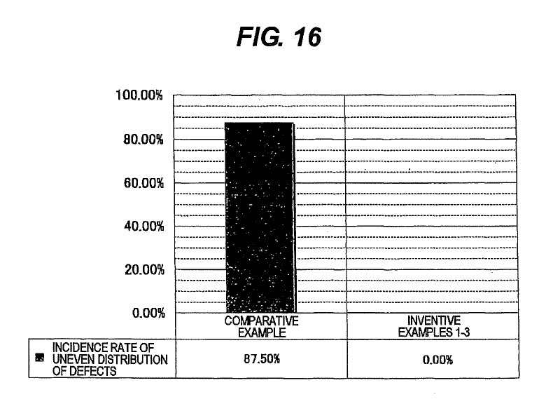

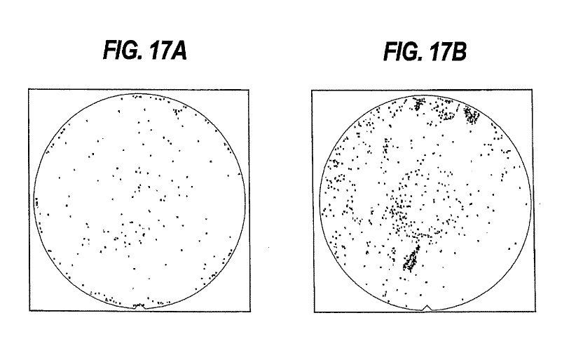

FIG. 16 is a graph showing the measured result of an incidence rate of uneven distribution of defects in the Inventive Examples 1, 2 and 3, and the Comparative Example. FIG. 17A is a view showing the state of the uneven distribution of defects over the substrate surface in the Inventive Example 1, and FIG. 17B is a view showing the state of the uneven distribution of defects over the substrate surface in the Comparative Example.

It is understood from FIGS. 16 and 17 that the uneven distribution of defects does not occur on the substrate surface in the Inventive Examples 1, 2 and 3.

According to the present invention, the surface of the substrate can be cleaned with a high cleaning level even when the surface of the substrate has a hydrophobic property. Specifically, since damascene interconnects are formed by using copper as an interconnect metal and a low-k film as an insulating film, copper and the low-k film having hydrophobic properties are exposed on the surface of the substrate after CMP. Even in such a case, the surface of the substrate can be cleaned with a high cleaning level, thereby reducing the number of defects remaining on the surface.

Although certain preferred embodiments of the present invention have been shown and described in detail, it should be understood that various changes and modifications may be made without departing from the scope of the appended claims.

What is claimed is:

1. A substrate cleaning apparatus for performing scrub cleaning of a surface of a substrate with an elongated roll cleaning member extending horizontally over substantially the entire length of a diameter of the substrate, by keeping said roll cleaning member and the surface of the substrate in contact with each other in the presence of a cleaning liquid while rotating the substrate and said roll cleaning member each in one direction, said substrate cleaning apparatus comprising:
a first chemical liquid supply nozzle configured to supply a chemical liquid onto one half area of two areas on the surface of the substrate which are divided by a line formed by vertically projecting a rotational axis of said roll cleaning member onto the surface of the substrate, said first chemical liquid supply nozzle comprising a nozzle configured to supply the chemical liquid toward the substrate so that the chemical liquid is brought into contact with the surface of the substrate in a first contact area extending in an elongated shape;
a second chemical liquid supply nozzle configured to supply a chemical liquid onto said one half area of said two areas, said second chemical liquid supply nozzle comprising a nozzle configured to supply the chemical liquid toward the substrate so that the chemical liquid is brought into contact with the surface of the substrate in a second contact area spreading in an elliptical shape; and
a rinse liquid supply nozzle configured to supply a rinse liquid onto the surface of the substrate;
wherein said first chemical liquid supply nozzle and said second chemical liquid supply nozzle are arranged so that said first contact area is located at a downstream side of said second contact area along a rotational direction of the substrate, and said rinse liquid supply nozzle is arranged so that the rinse liquid is brought into contact with the substrate at an upstream side of said second contact area along said rotational direction of the substrate.

2. A substrate cleaning apparatus according to claim 1, wherein said one half area is a roll rolling-out-side area where the cleaning liquid is scraped out by rotation of said roll cleaning member.

3. A substrate cleaning apparatus according to claim 2, wherein the cleaning liquid is supplied to said roll cleaning member from a direction of a roll rolling-in-side area where the cleaning liquid is rolled in by rotation of said roll cleaning member.

4. A substrate cleaning apparatus according to claim 2, wherein said one half area comprises both of a roll rolling-out-side area where the cleaning liquid is scraped out by rotation of said roll cleaning member and a roll rolling-in-side area where the cleaning liquid is rolled in by rotation of said roll cleaning member.

5. A substrate cleaning apparatus according to claim 1, wherein said first contact area is located at a downstream side along said rotational direction of the substrate in said one half area, and extends in substantially parallel to said roll cleaning member.

6. A substrate cleaning apparatus according to claim 1, wherein said first contact area extends in substantially parallel to said roll cleaning member from a location near an outer peripheral edge of the substrate and beyond a straight line which passes over a rotation center of the substrate and extends horizontally in a direction perpendicular to said rotational axis of said roll cleaning member.

7. A substrate cleaning apparatus according to claim 6, wherein in the case where an angle between a line formed by vertically projecting a center line of the chemical liquid ejection of said first chemical liquid supply nozzle onto the surface of the substrate, and a straight line which intersects with said projected line, formed by vertically projecting the center line of the chemical liquid ejection of said first chemical liquid supply nozzle, in said first contact area and extends in the direction perpendicular to said rotational axis of said roll cleaning member is taken as θ₁, and said angle as viewed in a clockwise direction from said straight line is assumed as a positive angle, said angle θ₁ is set to be −80°≦θ₁≦60°.

8. A substrate cleaning apparatus according to claim 1, wherein a line formed by vertically projecting a center line of the chemical liquid ejection of said second chemical liquid supply nozzle intersects with a line extending along a rotational axis of said roll cleaning member at a rotation center of the substrate or at a downstream side of said rotation center of the substrate along said rotational direction of the substrate.

9. A substrate cleaning apparatus according to claim 8, wherein an angle between said line formed by vertically projecting said center line of the chemical liquid ejection of said second chemical liquid supply nozzle and said line extending along said rotational axis of said roll cleaning member is not less than 30° and less than 90°.

10. A substrate cleaning apparatus according to claim 1, wherein a line formed by vertically projecting a center line of the rinse liquid ejection of said rinse liquid supply nozzle intersects with a line extending along a rotational axis of said roll cleaning member at a rotation center of the substrate or at a downstream side of said rotation center of the substrate along said rotational direction of the substrate.

11. A substrate cleaning apparatus according to claim 10, wherein an angle between said line formed by vertically projecting said center line of the rinse liquid ejection of said rinse liquid supply nozzle and said line extending along said rotational axis of said roll cleaning member is not less than 10° and not more than 60°.

12. A substrate cleaning method for performing scrub cleaning of a surface of a substrate with an elongated roll cleaning member extending horizontally over substantially the entire length of a diameter of the substrate, by keeping said roll cleaning member and the surface of the substrate in contact with each other in the presence of a cleaning liquid while rotating the substrate and said roll cleaning member each in one direction, said substrate cleaning method comprising:
supplying a chemical liquid so that the chemical liquid is brought into contact with the surface of the substrate in a first contact area extending in an elongated shape in one half area of two areas on the surface of the substrate which are divided by a line formed by vertically projecting a rotational axis of said roll cleaning member onto the surface of the substrate;
supplying a chemical liquid so that the chemical liquid is brought into contact with the surface of the substrate in a second contact area spreading in an elliptical shape and located at an upstream side of said first contact area along said rotational direction of the substrate in said one half area of said two areas;
keeping said roll cleaning member in contact with the surface of the substrate to perform scrub cleaning of the surface of the substrate; and
supplying a rinse liquid to rinse the surface of the substrate, after separating said roll cleaning member from the surface of the substrate and stopping supply of the chemical liquid from said first chemical liquid supply nozzle and said second chemical liquid supply nozzle, so that the rinse liquid is brought into contact with the substrate at an upstream side of said second contact area along said rotational direction of the substrate.

13. A substrate cleaning method according to claim 12, wherein said one half area is a roll rolling-out-side area where the cleaning liquid is scraped out by rotation of said roll cleaning member.

14. A substrate cleaning method according to claim 12, wherein the cleaning liquid is supplied to said roll cleaning member from a direction of a roll rolling-in-side area where the cleaning liquid is rolled in by rotation of said roll cleaning member.

15. A substrate cleaning method according to claim 12, wherein said one half area comprises a roll rolling-out-side area where the cleaning liquid is scraped out by rotation of said roll cleaning member and a roll rolling-in-side area where the cleaning liquid is rolled in by rotation of said roll cleaning member.

16. A substrate cleaning method according to claim 12, further comprising:
supplying a rinse liquid so that the rinse liquid is brought into contact with the substrate at a third contact area located at an upstream side of said second contact area along said rotational direction of the substrate.

17. A substrate cleaning method according to claim 12, wherein said first contact area is located at a downstream side along said rotational direction of the substrate in said one half area, and extends in substantially parallel to said roll cleaning member.

18. A substrate cleaning method according to claim 17, wherein said first contact area extends in substantially parallel to said roll cleaning member beyond a straight line which passes over a rotation center of the substrate and extends horizontally in a direction perpendicular to said rotational axis of said roll cleaning member.
